(19) United States
(12) Patent Application Publication
(10) Pub. No.: US 2007/0178697 A1
(43) Pub. Date: Aug. 2, 2007

(54) Copper electrodeposition in microelectronics

(75) Inventors: Vincent Paneccasio JR., Madison, CT (US); Xuan Lin, Northford, CT (US); Paul Figura, Orange, CT (US); Richard Hurtubise, Clinton, CT (US); Christian Witt, Woodbridge, CT (US)

Correspondence Address: SENNIGER POWERS, ONE METROPOLITAN SQUARE, 16TH FLOOR, ST LOUIS, MO, 63102, US

(73) Assignee: Enthone Inc., West Haven, CT (US)

(21) Appl. No.: 11/346,459

(22) Filed: Feb. 2, 2006

(51) Int. Cl. H01L 21/44

(52) U.S. Cl. 438/687

(57) ABSTRACT

An electrolytic plating method and composition for electrolytically plating Cu onto a semiconductor integrated circuit substrate having submicron-sized interconnect features. The composition comprises a source of Cu ions and a suppressor compound comprising polyether groups. The method involves rapid bottom-up deposition at a superfill speed by which Cu deposition in a vertical direction from the bottoms of the features to the top openings of the features is greater than Cu deposition on the side walls.

### FIELD OF THE INVENTION

This invention relates to a method, compositions, and additives for electrolytic Cu metallization in the field of microelectronics manufacture.

### BACKGROUND OF THE INVENTION

Electrolytic Cu metallization is employed in the field of microelectronics manufacture to provide electrical interconnection in a wide variety of applications, such as, for example, in the manufacture of semiconductor integrated circuit (IC) devices. The demand for manufacturing semiconductor IC devices such as computer chips with high circuit speed and high packing density requires the downward scaling of feature sizes in ultra-large-scale integration (ULSI) and very-large-scale integration (VLSI) structures. The trend to smaller device sizes and increased circuit density requires decreasing the dimensions of interconnect features. An interconnect feature is a feature such as a via or trench formed in a dielectric substrate which is then filled with metal to yield an electrically conductive interconnect. Further decreases in interconnect size present challenges in metal filling.

Copper has been introduced to replace aluminum to form the connection lines and interconnects in semiconductor substrates. Copper has a lower resistivity than aluminum and the thickness of a Cu line for the same resistance can be thinner than that of an aluminum line.

The use of copper has introduced a number of requirements into the IC manufacturing process. First, copper has a tendency to diffuse into the semiconductor's junctions, thereby disturbing their electrical characteristics. To combat this occurrence, a barrier layer, such as titanium nitride, tantalum, tantalum nitride, or other layers as are known in the art, is applied to the dielectric prior to the copper layer's deposition. It is also necessary that the copper be deposited on the barrier layer cost-effectively while ensuring the requisite coverage thickness for carrying signals between the IC's devices. As the architecture of ICs continues to shrink, this requirement proves to be increasingly difficult to satisfy.

One conventional semiconductor manufacturing process is the copper damascene system. Specifically, this system begins by etching the circuit architecture into the substrate's dielectric material. The architecture is comprised of a combination of the aforementioned trenches and vias. Next, a barrier layer is laid over the dielectric to prevent diffusion of the subsequently applied copper layer into the substrate's junctions, followed by physical or chemical vapor deposition of a copper seed layer to provide electrical conductivity for a sequential electrochemical process. Copper to fill into the vias and trenches on substrates can be deposited by plating (such as electroless and electrolytic), sputtering, plasma vapor deposition (PVD), and chemical vapor deposition (CVD). It is generally recognized electrochemical deposition is the best method to apply Cu since it is more economical than other deposition methods and can flawlessly fill into the interconnect features (often called “bottom up” growth). After the copper layer has been deposited, excess copper is removed from the facial plane of the dielectric by chemical mechanical polishing, leaving copper in only the etched interconnect features of the dielectric. Subsequent layers are produced similarly before assembly into the final semiconductor package.

Copper plating methods must meet the stringent requirements of the semiconductor industry. For example, Cu deposits must be uniform and capable of flawlessly filling the small interconnect features of the device, for example, with openings of 100 nm or smaller.

Electrolytic Cu systems have been developed which rely on so-called “superfilling” or “bottom-up growth” to deposit Cu into high aspect ratio features. Superfilling involves filling a feature from the bottom up, rather than at an equal rate on all its surfaces, to avoid seams and pinching off that can result in voiding. Multi-part systems consisting of a suppressor and an accelerator as additives have been developed for superfilling, as in Too et al., U.S. Pat. No. 6,776,893, which discloses polysulfide-based compounds for accelerating and a polyether-based compound for suppressing. As the result of momentum of bottom-up growth, the Cu deposit is thicker on the areas of interconnect features than on the field area that does not have features. These overgrowth regions are commonly called overplating, mounding, bumps, or humps. Smaller features generate higher overplating humps due to faster superfill speed. The overplating poses challenges for later chemical and mechanical polishing processes that planarize the Cu surface. A third organic additive called a “leveler” is typically used to address overgrowth and other issues, as in Commander et al., U.S. Pub. No. 2003/0168343.

As chip architecture gets smaller, with interconnects having openings on the order of 100 nm and smaller through which Cu must grow to fill the interconnects, there is a need for enhanced bottom-up speed. That is, the Cu must fill “faster” in the sense that the rate of vertical growth from the feature bottom in the direction of the feature opening must be substantially greater than the rate of growth on the rest of areas, and even more so than in conventional superfilling of larger interconnects.

In addition to superfilling and overplating issues, micro-defects may form when electrodepositing Cu for filling interconnect features. One defect that can occur is the formation of internal voids inside the features. As Cu is deposited on the feature side walls and top entry of the feature, deposition on the side walls and entrance to the feature can pinch off and thereby close access to the depths of the feature especially with features which are small (e.g., <100 nm) and/or which have a high aspect ratio (depth:width) if the bottom-up growth rate is not fast enough. Smaller feature size or higher aspect ratio generally requires faster bottom-up speed to avoid pinching off. Moreover, smaller size or higher aspect ratio features tend to have thinner seed coverage on the sidewall and bottom of a via/trench where voids can also be produced due to insufficient copper growth in these areas. An internal void can interfere with electrical connectivity through the feature.

Microvoids are another type of defect which can form during or after electrolytic Cu deposition due to uneven Cu growth or grain recrystallization that happens after Cu plating.

In a different aspect, some local areas of a semiconductor substrate may not grow Cu during the electrolytic deposition, resulting in pits or missing-metal defects. These Cu losses can occur on patterned or unpatterned wafer areas and are considered to be “killer defects” as they reduce the yield of semiconductor manufacturing products. Multiple mechanisms contribute to the formation of these Cu voids, including the semiconductor substrate itself. However, Cu electroplating chemistry, particularly the chemical structure and physical properties of an included suppressor compound in the electrolytic bath, can influence the occurrence and population of these defects. There are significant efforts in the semiconductor industry to control the missing metal type defects.

### SUMMARY OF THE INVENTION

In one aspect, the invention is directed to a method for electroplating a copper deposit onto a semiconductor integrated circuit device substrate with electrical interconnect features including submicron-sized features having bottoms, sidewalls, and top openings, the method comprising:
immersing the semiconductor integrated circuit device substrate into the electrolytic plating composition comprising an acid, a source of Cu ions in an amount sufficient to electrolytically deposit Cu onto the substrate and into the electrical interconnect features, and a suppressor compound which is a polyether chain covalently bonded to an initiating moiety comprising an ether group derived from an alcohol, the suppressor compound being bath soluble and bath compatible and having the following structure: 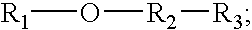
   wherein R₁ is an initiating moiety derived from a substituted or unsubstituted acyclic alcohol having between 1 and about 12 carbons, a substituted or unsubstituted cyclic alcohol preferably having 5 to 7 carbons, or a polyol comprising a hydroxyl group;
R₂ is a random polyether chain comprising EO units and PO units; and
R₃ is selected from the group consisting of hydrogen, substituted or unsubstituted alkyl group, aryl group, aralkyl, or heteroaryl group; and
supplying electrical current to the electrolytic composition to deposit Cu onto the substrate and superfill the submicron-sized features by rapid bottom-up deposition.

In another aspect, the invention is directed to a method for electroplating a copper deposit onto a semiconductor integrated circuit device substrate with electrical interconnect features including submicron-sized features having bottoms, sidewalls, and top openings, the method comprising:
immersing the semiconductor integrated circuit device substrate into the electrolytic plating composition comprising a source of Cu ions in an amount sufficient to electrolytically deposit Cu onto the substrate and into the electrical interconnect features and a suppressor compound which is a PO/EO random copolymer being bath soluble and bath compatible and having the structure: 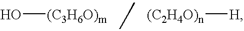
   wherein n is between 1 and about 550, m is between 1 and about 125, and the suppressor compound has a molecular weight of at least about 2800 g/mole, and
supplying electrical current to the electrolytic composition to deposit Cu onto the substrate and superfill the submicron-sized features by rapid bottom-up deposition.

In still another aspect, the invention is directed to an electrolytic plating composition for electrolytically plating a copper deposit onto a semiconductor integrated circuit device substrate with electrical interconnect features including submicron-sized features having bottoms, sidewalls, and top openings, the composition comprising an acid, a source of Cu ions in an amount sufficient to electrolytically deposit Cu onto the substrate and into the electrical interconnect features, and a suppressor compound which is a PO/EO random copolymer being bath soluble and bath compatible, the suppressor compound having a structure selected from among (a) and (b): 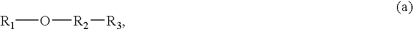
wherein
R₁ is an initiating moiety derived from a substituted or unsubstituted acyclic alcohol having between 1 and about 12 carbons, a substituted or unsubstituted cyclic alcohol preferably having 5 to 7 carbons, or a polyol comprising a hydroxyl group;
R₂ is a random polyether chain comprising EO units and PO units; and
R₃ is selected from the group consisting of hydrogen, substituted or unsubstituted alkyl group, aryl group, aralkyl, or heteroaryl group; and 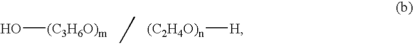
   wherein
n is between 1 and about 550;
m is between 1 and about 125; and
the suppressor compound has a molecular weight of at least about 2800 g/mole.

Other objects and features will be in part apparent and in part pointed out hereinafter.

### BRIEF DESCRIPTION OF THE DRAWINGS

FIGS. 1A and 1B are SEM images showing superfilled test trenches prepared according to the method of Example 6.

FIGS. 2A and 2B are SEM images showing superfilled test trenches prepared according to the method of Example 7.

FIGS. 3A and 3B are SEM images showing superfilled test trenches prepared according to the method of Example 8.

FIGS. 4A and 4B are SEM images showing superfilled test trenches prepared according to the method of Example 9.

### DETAILED DESCRIPTION OF THE INVENTION

In accordance with this invention, compositions are provided which are suitable for plating semiconductor integrated circuit substrates having challenging fill characteristics, such as interconnect features that are poorly seeded or not substantially seeded, interconnect features having a complex geometry, and large dimension interconnect features as well as small dimension features (less than about 0.5 μm), and features with high aspect ratios (at least about 3:1) or low aspect ratios (less than about 3:1) where Cu must fill all the features completely and substantially defect-free.

The compositions for Cu superfilling of semiconductor integrated circuit substrates having challenging fill characteristics of the present invention comprise a suppressor compound and a source of Cu ions. These compositions also typically comprise a leveler, an accelerator, and chloride. The above-listed additives find application in high Cu metal/low acid electrolytic plating baths, in low Cu metal/high acid electrolytic plating baths, and in mid acid/high Cu metal electrolytic plating baths. Compositions comprising the suppressor, leveler, and accelerator of the present invention can be used to fill small diameter/high aspect ratio features.

Preferred suppressors for the Cu plating compositions of the present invention comprise a polyether chain. In one aspect, the polyether chain can be covalently bonded to an initiating moiety comprising an ether group derived from an alcohol. Accordingly, the suppressor can comprise at least two distinct ether functional groups: (1) an ether group derived from a reaction between the alcohol and a random glycol unit of the polyether chain, and (2) ether groups derived from reactions between random glycol units within the polyether chain. In another aspect the polyether chain lacks an initiating moiety, and therefore lacks an ether group derived from a reaction between the alcohol or any other initiating moiety and a random glycol unit of the polyether chain.

In those embodiments where the polyether chain comprises an initiating moiety comprising an ether group derived from an alcohol, suitable alcohols include substituted or unsubstituted acyclic alcohols and substituted or unsubstituted cyclic alcohols. The alcohol comprises at least one hydroxyl group, and thus can be an alcohol or a polyol, the polyol suitably comprising two or more hydroxyl groups, suitably between about two hydroxyl groups and about six hydroxyl groups. Acyclic alcohols comprise a substituted or unsubstituted alkyl, preferably a short chain hydrocarbon having between one and about twelve carbons, preferably between about four and about ten carbons, which may be branched or straight chained. Exemplary acyclic alcohols include n-butanol, iso-butanol, tert-butanol, pentanol, neopentanol, tert-amyl alcohol, ethylene glycol, 1,2-butanediol, 1,3-butandiol, 1,4-butanediol, and glycerol among others. Cycloalkyl groups typically comprise a 5- to 7-carbon ring, although bicylic, tricylic, and higher multi-cyclic alkyl groups are applicable. Exemplary cyclic alcohols include cyclopentanol, 1,2-cyclopentanediol, 1,3-cyclopentanediol, cyclohexanol, 1,2-cyclohexanediol, 1,3-cyclohexanediol, 1,4-cyclohexanediol, and inositol among others.

The polyethers comprise a chain of random glycol units, wherein the chain of random glycol units can be formed by the polymerization of epoxide monomers. In a preferred embodiment, the epoxide monomers are selected from ethylene oxide monomer, propylene oxide monomer, and a combination thereof. Preferably, the polyether comprises a chain of random glycol units formed by the polymerization of both ethylene oxide monomer and propylene oxide monomer. Accordingly, the ratio of ethylene oxide (EO) glycol units and propylene oxide (PO) glycol units in the polyether can be between about 1:9 and about 9:1. In one embodiment, the ratio is between about 1:3 and about 3:1, such as about 1:1. The random polyether can comprise up to about 800 EO glycol units and up to about 250 PO glycol units. In one embodiment, the random polyether comprises between about 1 and about 120 EO glycol units and between about 120 and about 1 PO glycol units, such as between about 15 and about 60 EO glycol units and between about 60 and about 15 PO glycol units. In a preferred embodiment, the random polyether comprises between about 20 and about 25 EO glycol units and between about 15 and about 20 PO glycol units. In another preferred embodiment, the random polyether comprises between about 38 and about 42 EO glycol units and between about 28 and about 32 PO glycol units. In yet another preferred embodiment, the random polyether comprises between about 56 and about 60 EO glycol units and between about 42 and about 46 PO glycol units.

The molecular weight of the random polyether can be as low as about 1000 g/mole and as high as about 90,000 g/mole, preferably between about 3000 g/mole and about 30,000 g/mole, and more preferably, between about 3000 g/mole and about 12,000 g/mole. Suppressors according to the present invention provide dual benefits of faster bottom-up fill speed and low defectivity in the as-plated Cu deposit. It has been observed that having too low of a molecular weight slows the fill speed.

Optionally, the PO/EO polyethers are capped by a substituted or unsubstituted alkyl group, aryl group, aralkyl, or heteroaryl group. A preferred capping moiety for its ease of manufacture and low cost is a methyl group.

The suppressor compounds of the invention comprise EO glycol units and PO glycol units arranged in a random configuration, rather than a block or ordered alternating configuration. It is thought that the separate functionalities of the EO units and the PO units contribute different chemical and physical properties which affect, and thereby enhance, the function of the random polyether as a suppressor in the Cu plating compositions of the present invention. It is believed that the PO unit is the active unit in the suppressors of the present invention. That is, the PO unit has suppressor functionality and affects the quality of the Cu deposit. Without being bound to a particular theory, it is thought that the PO units, being relatively hydrophobic, form a polarizing film over a Cu seed layer and electrolytically deposited Cu.

A Cu seed layer is typically deposited over the barrier layer in interconnect features by CVD, PVD, and other methods known in the art. The Cu seed layer acts as the cathode for further reduction of Cu that superfills the interconnects during the electrolytic plating operation. Cu seed layers can be thin, i.e., less than about 700 Angstroms. Or they may be thick, i.e., between about 700 Angstroms and about 1500 Angstroms. However, the copper thickness on the bottom or sidewall of features is typically much thinner than those on the feature top and unpatterned areas due to the non-uniform deposition rates of PVD processes. In some extreme circumstances, the copper coverage on the bottom or sidewall could be so thin that the seed is discontinuous. In another case, the seed coverage on the top of features is thicker than on other feature areas, which is often called “seed overhang.” Generally, the uniformity of seed coverage degrades significantly with shrinking feature size and increasing aspect ratio. The present invention has been shown to perform well, and better than the prior art, with thin or overhanged seed layers.

The suppressor compound with somewhat hydrophobic PO units is able to form a suppressive film over the Cu seed layer. In the case of thin copper seed coverage, this polarizing organic film will cause the current to be more evenly distributed over the entire interconnect feature, i.e., the bottom and sidewalls of the via or trench. Even current distribution is believed to promote faster bottom up growth relative to sidewall growth, and may also reduce or eliminate bottom and sidewall voiding. This strongly suppressive suppressor is also desirable to suppress copper growth at the seed overhang areas on the top of the interconnect features, reducing the formation of internal voids from early pinching off. It has been discovered that the suppressor compound comprising a random polyether chain is effective at suppressing Cu deposition over thin or thick Cu seed layers. A polyether constituted only of PO units, being relatively hydrophobic, lacks the solubility necessary to act as an adequate suppressor. That is, while PO is a superior suppressor, a polymer constituted only of PO units may not be soluble enough to go into the Cu plating solution so that it can adsorb onto the Cu seed layer in a high enough concentration to form a polarizing film. Accordingly, the random polyether chain further comprises EO units to enhance its hydrophilicity and thus its solubility.

In addition to the voids resulted from insufficient trench or via fill, defects can also form on patterned or unpatterned wafer surfaces regardless of gapfill performance. For example, local areas of wafer substrate may have skip plating during electrolytic copper deposition, leading to pits or missing metal defects. These copper losses will reduce the yield of semiconductor wafer devices so they are considered as “killer defects” that are targeted for reduction or elimination. It has been observed that the random copolymers of PO and EO as suppressors greatly reduce the occurrence and population of those pitting type defects. The random copolymers outperform block copolymers in reduction of copper post plating defects and post CMP defects, particularly missing metal pits.

The suppressors comprising a polyether group covalently bonded to an initiating moiety derived from an alcohol have the following structure (1): 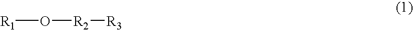
wherein
R₁ is an initiating moiety derived from a substituted or unsubstituted acyclic alcohol preferably having between 1 and about 12 carbons or a substituted or unsubstituted cyclic alcohol preferably having 5 to 7 carbons. In some embodiments, R₁ is a polyol substituted with another hydroxyl group to which a random polyether chain is covalently bonded, the random polyether chain comprising EO units, PO units, or a combination thereof;
R₂ is a random polyether chain preferably comprising EO units, PO units, or a combination thereof; and
R₃ is selected from the group consisting of hydrogen, substituted or unsubstituted alkyl group, aryl group, aralkyl, or heteroaryl group.

An exemplary suppressor compound of structure (1) comprising a polyether group covalently bonded to a moiety derived from an alcohol is shown by structure (2). Structure (2) is a suppressor comprising a PO/EO random copolymer covalently bonded to a moiety derived from n-butanol having the structure: 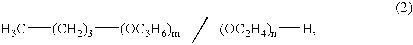
wherein n can be between 1 and about 200 and m can be between 1 and about 200. Preferably, n is at least about 29 and m is at least about 22. The number ratio of EO:PO units is such that the suppressor compound preferably comprises between about 45% and about 55% by weight EO units and between about 55% and about 45% by weight PO units, the EO and PO units arranged randomly in the polyether chain. In one exemplary suppressor compound, the suppressor comprises about 50% by weight EO units and about 50% by weight PO units arranged randomly in the polyether chain. The molecular weight of the random PO/Eo copolymer can be between about 1000 g/mole and about 10,000 g/mole, at least 2800 g/mole, and preferably between about 3000 g/mole and about 4000 g/mole. The inventors have discovered that a suppressor compound having structure (2) random characterized by a molecular weight between about 3000 g/mole and about 4000 g/mole and having about EO:PO weight ratio between about 45:55 and about 55:45, such as 50:50, is an especially advantageous suppressor in terms of fast “bottom-up” filling with low plated Cu defectivity. A suppressor meeting these parameters is shown in Example 1. While suppressor compounds outside these advantageous ranges are applicable in the Cu plating baths of the present invention, applicants have discovered surprisingly superior results within these narrow parameters.

An exemplary suppressor compound having the structure (2) is available from The Dow Chemical Company of Midland, Mich. under the trade designation UCON™ 50HB 2000. It is also available from BASF under the trade name of PLURASAFE WS Fluids and from Huntsman under the trade name of WS-4000. The suppressor's UCON designation is indicative of its composition. That is, 50HB indicates that about 50% of the suppressor's molecular weight is due to EO units and about 50% of its molecular weight is due to PO units. Accordingly, UCON™ 50HB 2000 comprises about 22 PO units in the random PO/EO copolymer and about 29 EO units in the random PO/EO copolymer. Another exemplary random copolymer of structure (2), also available from The Dow Chemical Company, is sold under the trade designation UCON™ 50HB 3520. This suppressor compound comprises about 28 PO units in the random PO/EO copolymer and about 38 EO units in the random PO/EO copolymer. Yet another exemplary random copolymer of structure (2), also available from The Dow Chemical Company, is sold under the trade designation UCON™ 50HB 5100. This suppressor compound comprises about 33 PO units in the random PO/EO copolymer and about 44 EO units in the random PO/EO copolymer. The bath composition can comprise a mixture of random copolymers of structure (2).

As noted above, in an alternative embodiment the suppressor compound can comprise a polyether chain which lacks an initiating moiety, such as an alcohol or amine. Accordingly, the suppressor compound comprising a PO/EO random copolymer can have the structure (3): 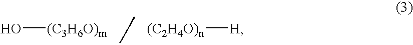
wherein n can be between 1 and about 550 and m can be between 1 and about 125. Preferably, n is at least about 200 and m is at least about 50. The number ratio of EO:PO units is such that the suppressor compound preferably comprises between about 70% and about 75% by weight EO units and between about 30% and about 25% by weight PO units, the EO and PO units arranged randomly in the polyether chain. In one exemplary suppressor compound, the suppressor comprises about 75% by weight EO units and about 25% by weight PO units arranged randomly in the polyether chain. The molecular weight of the random PO/EO copolymer is at least about 2800 g/mole and can be between about 3000 g/mole and about 30,000 g/mole, preferably between about 11,000 g/mole and about 13,000 g/mole. One exemplary suppressor compound has a molecular weight of about 12,000 g/mole. Suppressors having structure (3) can be prepared by adding base initiator, such as NaOH or KOH, to a solution comprising both PO and EO monomer units, which are present in solution in concentrations sufficient to achieve random polyether chains comprising the PO and EO units in the desired ratio. The base initiators are not incorporated into the polyether, such that the polyether comprises only PO and EO units in a random configuration. The inventors have discovered that a suppressor compound having structure (3) characterized by a molecular weight of about 10,000 to 12,000 g/mole and having an EO:PO weight ratio between about 65:35 and about 75:25 arranged randomly in the polyether chain is an especially advantageous suppressor in terms of fast “bottom-up” filling with low plated Cu defectivity. A suppressor meeting these parameters is shown in Example 5. While suppressor compounds outside these advantageous ranges are applicable in the Cu plating baths of the present invention, applicants have discovered surprisingly superior results within these narrow parameters.

An exemplary suppressor compound having structure (3) is available from The Dow Chemical Company of Midland, Mich. under the trade designation UCON™ 75H 90,000. UCON™ 75H 90,000 comprises about 52 PO units in the random PO/EO copolymer and about 204 EO units in the random PO/EO copolymer.

In all embodiments, the suppressor is bath compatible as determined by its cloud point and solubility. Preferably, the cloud point of the suppressor is higher than the bath operating temperatures, which are typically at room temperature, but may be as high as about 40° C. or somewhat higher. The suppressor compounds described above have sufficient solubility in aqueous solution such that they can be present in an overall bath concentration between about 10 mg/L to about 1000 mg/L, preferably between about 100 mg/L to about 300 mg/L. Adding the polyether suppressors to Cu plating compositions within these concentration ranges is sufficient to fill complex features in an integrated circuit device, with the added benefits of reducing early pinching off, bottom voiding, or sidewall voiding.

The composition of the invention also preferably includes a leveler which has an enhanced leveling effect without substantially interfering with superfilling of Cu into high aspect ratio features. One such preferred leveler is disclosed in U.S. Pat. Pub. No. 2005/0045488, filed Oct. 12, 2004, the entire disclosure of which is expressly incorporated by reference. This leveler does not substantially interfere with superfilling, so the Cu bath can be formulated with a combination of accelerator and suppressor additives which provides a rate of growth in the vertical direction which is substantially greater than the rate of growth in the horizontal direction, and even more so than in conventional superfilling of larger interconnects. One such preferred leveler is a reaction product of 4-vinyl pyridine and methyl sulfate available from Enthone Inc. under the trade name ViaForm L700. The leveler is incorporated, for example, in a concentration between about 0.1 mg/L and about 25 mg/L. Another is the reaction product of 4-vinyl pyridine and 1,3 dichloropropanol according to example 20 of 2005/0045488, which is the leveler employed in below example 4.

With regard to accelerators, in a system currently preferred by the applicants, the accelerators are bath soluble organic divalent sulfur compounds as disclosed in U.S. Pat. No. 6,776,893, the entire disclosure of which is expressly incorporated by reference. In one preferred embodiment, the accelerator corresponds to the formula (4)
R₁—(S)ₙRXO₃M (4),
wherein
M is hydrogen, alkali metal or ammonium as needed to satisfy the valence;
X is S or P;
R is an alkylene or cyclic alkylene group of 1 to 8 carbon atoms, an aromatic hydrocarbon or an aliphatic aromatic hydrocarbon of 6 to 12 carbon atoms;
n is 1 to 6; and
R₁ is MO₃XR wherein M, X and R are as defined above.

An accelerator which is especially preferred is 1-propanesulfonic acid, 3,3′-dithiobis, disodium salt according to the following formula (5):

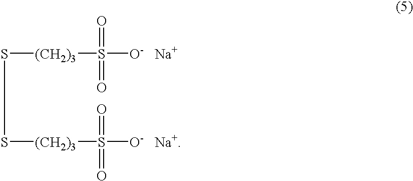

The accelerator is incorporated typically in a concentration between about 0.5 and about 1000 mg/L, more typically between about 2 and about 50 mg/L, such as between about 5 and 30 mg/L. A significant aspect of the current invention is that it permits the use of a greater concentration of accelerator, and in many applications in fact it must be used in conjunction with a greater concentration of accelerator than in conventional processes. This permits achieving the enhanced rates of superfilling demonstrated below.

Optionally, additional leveling compounds of the following types can be incorporated into the bath such as the reaction product of benzyl chloride and hydroxyethyl polyethylenimine as disclosed in U.S. Pat. Pub. No. 2003/0168343, the entire disclosure of which is expressly incorporated herein by reference.

The components of the Cu electrolytic plating bath may vary widely depending on the substrate to be plated and the type of Cu deposit desired. The electrolytic baths include acid baths and alkaline baths. A variety of Cu electrolytic plating baths are described in the book entitled Modern Electroplating, edited by F. A. Lowenheim, John Reily & Sons, Inc., 1974, pages 183-203. Exemplary Cu electrolytic plating baths include Cu fluoroborate, Cu pyrophosphate, Cu cyanide, Cu phosphonate, and other Cu metal complexes such as methane sulfonic acid. The most typical Cu electrolytic plating bath comprises Cu sulfate in an acid solution.

The concentration of Cu and acid may vary over wide limits; for example, from about 4 to about 70 g/L Cu and from about 2 to about 225 g/L acid. In this regard the compounds of the invention are suitable for use in distinct acid/Cu concentration ranges, such as high acid/low Cu systems, in low acid/high Cu systems, and mid acid/high Cu systems. In high acid/low Cu systems, the Cu ion concentration can be on the order of 4 g/L to on the order of 30 g/L; and the acid concentration may be sulfuric acid in an amount of greater than about 100 g/L up to about 225 g/L. In one high acid/low Cu system, the Cu ion concentration is about 17 g/L where the H₂SO₄ concentration is about 180 g/L. In some low acid/high Cu systems, the Cu ion concentration can be between about 35 g/L and about 60 g/L, such as between about 38 g/L and about 42 g/L. In some low acid/high Cu systems, the Cu ion concentration can be between about 46 g/L and about 60 g/L, such as between about 48 g/L and about 52 g/L. (35 g/L Cu ion corresponds to about 140 g/L CuSO₄.5H₂O Cu sulfate pentahydrate.) The acid concentration in these systems is preferably less than about 100 g/L. In some low acid/high Cu systems, the acid concentration can be between about 5 g/L and about 30 g/L, such as between about 10 g/L and about 15 g/L. In some low acid/high Cu, the acid concentration can be between about 50 g/L and about 100 g/L, such as between about 75 g/L to about 85 g/L. In an exemplary low acid/high Cu system, the Cu ion concentration is about 40 g/L and the H₂SO₄ concentration is about 10 g/L. In another exemplary low acid/high Cu system, the Cu ion concentration is about 50 g/L and the H₂SO4 concentration is about 80 g/L. In mid acid/high Cu systems, the Cu ion concentration can be on the order of 30 g/L to on the order of 60 g/L; and the acid concentration may be sulfuric acid in an amount of greater than about 50 g/L up to about 100 g/L. In one mid acid/high Cu system, the Cu ion concentration is about 50 g/L where the H₂SO₄ concentration is about 80 g/L.

Chloride ion may also be used in the bath at a level up to 200 mg/L, preferably about 10 to 90 mg/L. Chloride ion is added in these concentration ranges to enhance the function of other bath additives. These additives system include accelerators, suppressors, and levelers.

A large variety of additives may typically be used in the bath to provide desired surface finishes for the Cu plated metal. Usually more than one additive is used with each additive forming a desired function. At least two additives are generally used to initiate bottom-up filling of interconnect features as well as for improved metal physical (such as brightness), structural, and electrical properties (such as electrical conductivity and reliability). Particular additives (usually organic additives) are used for grain refinement, suppression of dendritic growth, and improved covering and throwing power. Typical additives used in electrolytic plating are discussed in a number of references including Modern Electroplating, cited above.

Plating equipment for plating semiconductor substrates is well known and is described in, for example, Haydu et al. U.S. Pat. No. 6,024,856. Plating equipment comprises an electrolytic plating tank which holds Cu electrolytic solution and which is made of a suitable material such as plastic or other material inert to the electrolytic plating solution. The tank may be cylindrical, especially for wafer plating. A cathode is horizontally disposed at the upper part of the tank and may be any type substrate such as a silicon wafer having openings such as trenches and vias. The wafer substrate is typically coated first with a barrier layer, which may be titanium nitride, tantalum, tantalum nitride, or ruthenium to inhibit Cu diffusion and next with a seed layer of Cu or other metal to initiate Cu superfilling plating thereon. A Cu seed layer may be applied by chemical vapor deposition (CVD), physical vapor deposition (PVD), or the like. An anode is also preferably circular for wafer plating and is horizontally disposed at the lower part of tank forming a space between the anode and cathode. The anode is typically a soluble anode such as copper metal.

The bath additives are useful in combination with membrane technology being developed by various tool manufacturers. In this system, the anode may be isolated from the organic bath additives by a membrane. The purpose of the separation of the anode and the organic bath additives is to minimize the oxidation of the organic bath additives on the anode surface.

The cathode substrate and anode are electrically connected by wiring and, respectively, to a rectifier (power supply). The cathode substrate for direct or pulse current has a net negative charge so that Cu ions in the solution are reduced at the cathode substrate forming plated Cu metal on the cathode surface. An oxidation reaction takes place at the anode. The cathode and anode may be horizontally or vertically disposed in the tank.

During operation of the electrolytic plating system, Cu metal is plated on the surface of a cathode substrate when the rectifier is energized. A pulse current, direct current, reverse periodic current, or other suitable current may be employed. The temperature of the electrolytic solution may be maintained using a heater/cooler whereby electrolytic solution is removed from the holding tank and flows through the heater/cooler and then is recycled to the holding tank.

In the case of thin copper seed coverage, less current will be delivered to the lower portions of interconnect features, which may lead to bottom or sidewall voids and slow bottom-up growth. For features which have seed overhang, the electrolytic copper growth may have early pinching off on the feature tops before the bottom-up growth can reach the surface. Conventional suppressors may not distribute enough current to the bottom of the interconnect feature to promote bottom-up superfilling rapid enough to prevent the pinching off of interconnect features by Cu electrolytic deposition leading to the formation of internal voids, especially for features seeded with a thin Cu seed layer. Also, conventional suppressors may not have strong enough suppression to suppress copper growth on seed overhang areas to prevent early pinching off. Without being bound to a particular theory, it is observed that the suppressor compounds of the present invention function to inhibit the formation of internal voids and enhance the bottom-up superfilling deposition rate by up to twice the rate over a typical electrolytic plating solution not comprising the suppressor compounds of the present invention by forming a polarizing film over the Cu seed layer. Also, the suppressor compounds of the present invention possess stronger suppression (more polarizing) than most conventional suppressors, which allows the current to be distributed more evenly over the Cu seed layer deposited on the bottom and sidewalls of the interconnect feature leading to the reduction or elimination of bottom and sidewall voids. An even current distribution enhances Cu growth at the bottom of the feature relative to deposition at other regions to such an extent that bottom-up superfilling occurs so rapidly that deposition at the side and top of the feature will not cause a pinching off of the deposit and the formation of internal voids. The suppressor compounds of the present invention are effective at rapid bottom-up superfilling over thin or overhanged Cu seed layers. For example, the suppressor compounds have been found effective to superfill an interconnect feature seeded with a thin Cu seed layer on the bottom and side walls of an interconnect feature having a thickness between about 1 Angstrom and about 100 Angstroms.

An advantage of adding the suppressor compounds of the present invention to electrolytic Cu plating solutions is the reduction in the occurrence of internal voids as compared to deposits formed from a bath not containing these compounds. Internal voids form from Cu depositing on the feature side walls and top entry of the feature, which causes pinching off and thereby closes access to the depths of the feature. This defect is observed especially with features which are small (e.g., <100 nm) and/or which have a high aspect ratio (depth:width), for example, >4:1. Those voids left in the feature can interfere with electrical connectivity of copper interconnects. The suppressor compounds of the invention appear to reduce the incidence of internal voids by the above-described rapid superfilling mechanism and strong suppression.

It is an optional feature of the process that the plating system be controlled as described in U.S. Pat. No. 6,024,856 by removing a portion of the electrolytic solution from the system when a predetermined operating parameter (condition) is met and new electrolytic solution is added to the system either simultaneously or after the removal in substantially the same amount. The new electrolytic solution is preferably a single liquid containing all the materials needed to maintain the electrolytic plating bath and system. The addition/removal system maintains a steady-state constant plating system having enhanced plating effects such as constant plating properties. With this system and method the plating bath reaches a steady state where bath components are substantially a steady-state value.

Electrolysis conditions such as electric current concentration, applied voltage, electric current density, and electrolytic solution temperature are essentially the same as those in conventional electrolytic Cu plating methods. For example, the bath temperature is typically about room temperature such as about 20-27° C., but may be at elevated temperatures up to about 40° C. or higher. The electrical current density is typically up to about 100 MA/cm², typically about 2 mA/cm² to about 60 mA/cm². It is preferred to use an anode to cathode ratio of about 1:1, but this may also vary widely from about 1:4 to 4:1. The process also uses mixing in the electrolytic plating tank which may be supplied by agitation or preferably by the circulating flow of recycle electrolytic solution through the tank. The flow through the electrolytic plating tank provides a typical residence time of electrolytic solution in the tank of less than about 1 minute, more typically less than 30 seconds, e.g., 10-20 seconds.

The following examples further illustrate the practice of the present invention.

### EXAMPLES

### Example 1

Low Acid/High Cu Superfill Electrolytic Plating Bath with Suppressor of the Invention

To superfill a small diameter/high aspect ratio integrated circuit device feature, a Low acid/High Cu electrolytic plating bath was prepared comprising the following components:
160 g/L CUSO₄.5H₂O (copper sulfate pentahydrate)
10 g/L H₂SO₄ (concentrated sulfuric acid)
50 mg/L Chloride ion
9 mL/L ViaForm® Accelerator
200 mg/L of Suppressor (random PO/EO copolymer of n-butanol having a MW of 3380 g/mole corresponding to structure (2)).

The bath (1 L) was prepared as follows: CuSO₄.5H₂O (160 g) was fully dissolved in deionized water. Concentrated sulfuric acid (10 g) was added followed by addition of hydrochloric acid sufficient to yield 50 mg chloride ion in solution. Deionized water was added for a total volume of 1 liter. The final plating bath was prepared by further addition of ViaForm Accelerator (9 mL) and Suppressor (200 mg).

### Comparative Example 1

Low Acid/High Cu Superfill Electrolytic Plating Bath with Comparative Suppressor

A comparative Low acid/High Cu electrolytic plating bath was prepared comprising the following components:
160 g/L CuSO₄.5H₂O (copper sulfate pentahydrate)
10 g/L H₂SO₄ (concentrated sulfuric acid)
50 mg/L Chloride ion
9 mL/L ViaForm® Accelerator
200 mg/L Commercially Available Suppressor having the following formula: 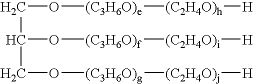
   wherein the sum of e+f+g=21 and the sum of h+i+j=27, available from Enthone Inc. under the trade name ViaForm Suppressor.

### Example 2

High Acid/Low Cu Superfill Electrolytic Plating Bath with Suppressor of the Invention

To superfill a small diameter/high aspect ratio integrated circuit device feature, a High Acid/Low Cu electrolytic plating bath was prepared comprising the following components:
70 g/L CuSO₄.5H₂O (copper sulfate pentahydrate)
180 g/L H₂SO₄ (concentrated sulfuric acid)
50 mg/L Chloride ion
5 mL/L ViaForm® Accelerator
400 mg/L Suppressor (random PO/EO copolymer of n-butanol having a MW of 3380 g/mole corresponding to structure (2)).

### Example 3

Mid Acid/High Cu Superfill Electrolytic Plating Bath with Suppressor of the Invention

To superfill a small diameter/low aspect ratio integrated circuit device feature, a Mid acid/High Cu electrolytic plating bath was prepared comprising the following components:
200 g/L CuSO₄.5H₂O (copper sulfate pentahydrate)
80 g/L H₂SO₄ (concentrated sulfuric acid)
50 mg/L Chloride ion
8 mL/L ViaForm® Accelerator
200 mg/L Suppressor (random PO/EO copolymer of n-butanol having a MW of 3930 g/mole corresponding to structure (2))
4 mL/L ViaForm® L700.

### Comparative Example 3

Mid Acid/High Cu Superfill Electrolytic Plating Bath with Suppressor of the Invention

To superfill a small diameter/low aspect ratio integrated circuit device feature, a Mid acid/High Cu electrolytic plating bath was prepared comprising the following components:
200 g/L CuSO₄.5H₂O (copper sulfate pentahydrate)
80 g/L H₂SO₄ (concentrated sulfuric acid)
50 mg/L Chloride ion
8 mL/L ViaForm® Accelerator
4 mL/L ViaForm® L700
200 mg/L Commercially Available Suppressor having the formula depicted in Comparative Example 1.

### Example 4

Low Acid/High Cu Superfill Electrolytic Plating Bath with Suppressor of the Invention

To superfill a small diameter/high aspect ratio integrated circuit device feature, a High Acid/Low Cu electrolytic plating bath was prepared comprising the following components:
160 g/L CuSO₄.5H₂O (copper sulfate pentahydrate)
10 g/L H₂SO₄ (concentrated sulfuric acid)
50 mg/L Chloride ion
18 mg/L 1-propanesulfonic acid, 3,3′-dithiobis, disodium salt
200 mg/L Suppressor (random PO/EO copolymer of n-butanol having a MW of 3380 g/mole corresponding to structure (2))
4.5 mL/L vinyl pyridine leveler.

### Comparative Example 4

Low Acid/High Cu Superfill Electrolytic Plating Bath with Suppressor of the Invention

To superfill a small diameter/low aspect ratio integrated circuit device feature, a Mid acid/High Cu electrolytic plating bath was prepared comprising the following components:
200 g/L CuSO₄.5H₂O (copper sulfate pentahydrate)
80 g/L H₂SO₄ (concentrated sulfuric acid)
50 mg/L Chloride ion
9 mL/L ViaForm® Accelerator
3 mL/L ViaForm® NEXT Leveler
200 mg/L Commercially Available Suppressor having the formula depicted in Comparative Example 1.

### Example 5

Low Acid/High Cu Superfill Electrolytic Plating Bath with Suppressor of the Invention

A Low acid/High Cu electrolytic plating bath was prepared comprising the following components:
160 g/L CuSO₄.5H₂O (copper sulfate pentahydrate)
10 g/L H₂SO₄ (concentrated sulfuric acid)
50 mg/L Chloride ion
9 mL/L ViaForm Accelerator
200 mg/L Suppressor (random PO/EO copolymer comprising
75% EO units and 25% PO units having a MW of 12,000 g/mole corresponding to structure (3)).

### Comparative Example 5

Low Acid/High Cu Superfill Electrolytic Plating Bath with Comparative Suppressor

To superfill a small diameter/high aspect ratio integrated circuit device feature, a Low acid/High Cu electrolytic plating bath was prepared comprising the following components:
160 g/L CuSO₄.5H₂O (copper sulfate pentahydrate)
10 g/L H₂SO₄ (concentrated sulfuric acid)
50 mg/L Chloride ion
9 mL/L ViaForm® Accelerator
200 mg/L Commercially Available Suppressor of Comparative Example 1.

### Example 6

Superfilling Test Trenches with Low Acid/High Cu Superfill Electrolytic Plating Bath

Test trenches (140 nm; aspect ratio between 3:1 and 4:1)) were superfilled with Cu using the low acid/high Cu electrolytic plating bath of Example 1 comprising a suppressor of the invention and compared to test trenches superfilled with Cu using the low acid/high Cu electrolytic plating bath of Comparative Example 1 comprising a commercially available suppressor.

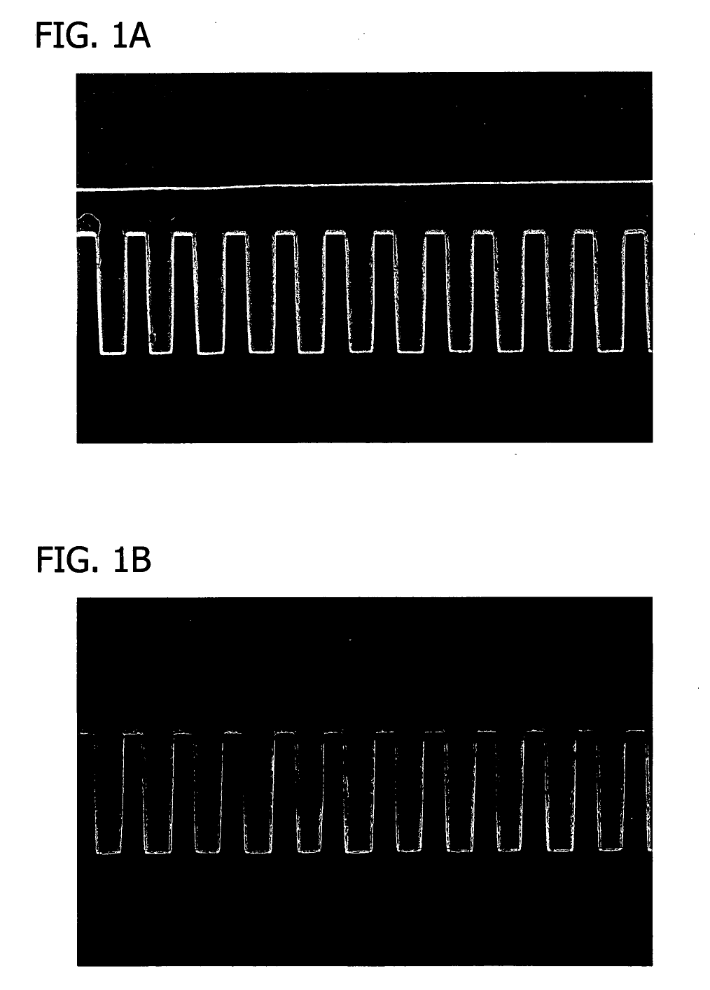

SEM images of the electrolytically plated Cu deposit in the test trenches are shown in FIGS. 1A and 1B. FIG. 1A is an SEM image of the test trenches electrolytically plated with the bath of Example 1. FIG. 1B is an SEM image of the test trenches electrolytically plated with the bath of Comparative Example 1. Both deposits were plated at a current density of 3.5 mA/cm² for 15 seconds to reveal the progression of bottom-up growth. It can be seen from the SEM images that superfilling using the bath of Example 1 achieved more complete via filling than electrolytically superfilling using the bath of Comparative Example 1, thus demonstrating substantially faster fill speed.

### Example 7

Superfilling Test Trenches with Mid Acid/High Cu Superfill Electrolytic Plating Bath

Test trenches (96 nm; aspect ratio between 3:1 and 4:1)) were superfilled with Cu using the mid acid/high Cu electrolytic plating bath of Example 3 comprising a suppressor of the invention and compared to test trenches superfilled with Cu using the mid acid/high Cu electrolytic plating bath of Comparative Example 3 comprising a commercially available suppressor.

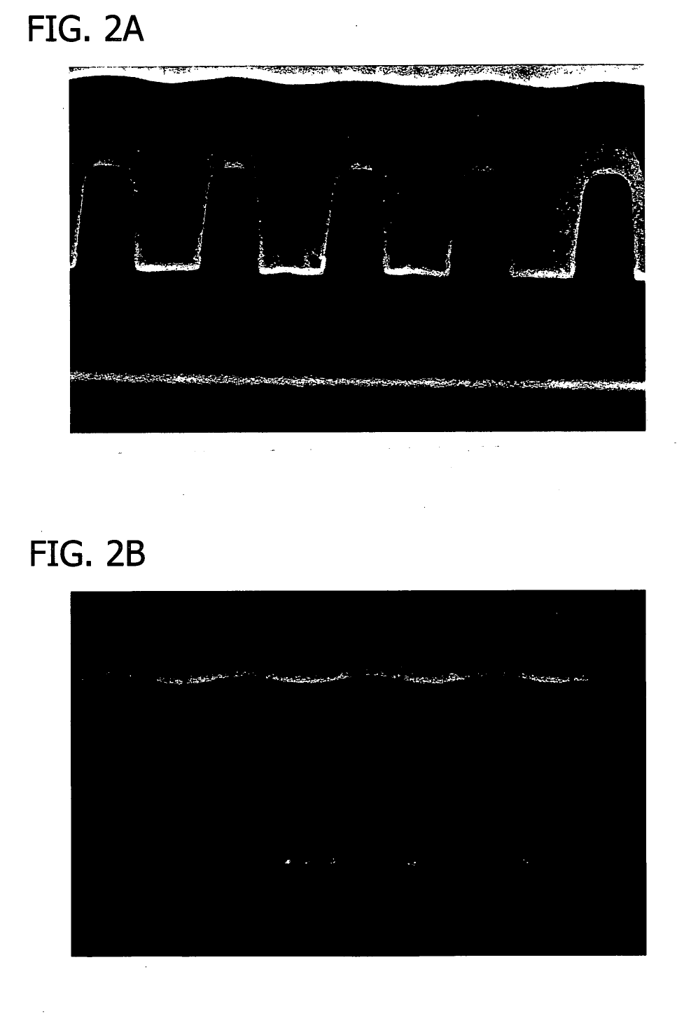

SEM images of the electrolytically plated Cu deposit in the test trenches are shown in FIGS. 2A and 2B. FIG. 2A is an SEM image of the test trenches electrolytically plated with the bath of Example 3. FIG. 2B is an SEM image of the test trenches electrolytically plated with the bath of Comparative Example 3. Both deposits were plated at a current density of 7 mA/cm² for 30 seconds to reveal the progression of bottom-up growth. It can be seen from the SEM images that superfilling using the bath of Example 3 achieved more complete via filling than electrolytically superfilling using the bath of Comparative Example 3, thus demonstrating substantially faster fill speed.

### Example 8

Superfilling Test Trenches with Low Acid/High Cu Superfill Electrolytic Plating Bath

Test trenches (180 nm; aspect ratio between 3:1 and 4:1)) were superfilled with Cu using the low acid/high Cu electrolytic plating bath of Example 4 comprising a suppressor of the invention and compared to test trenches superfilled with Cu using the low acid/high Cu electrolytic plating bath of Comparative Example 4 comprising a commercially available suppressor.

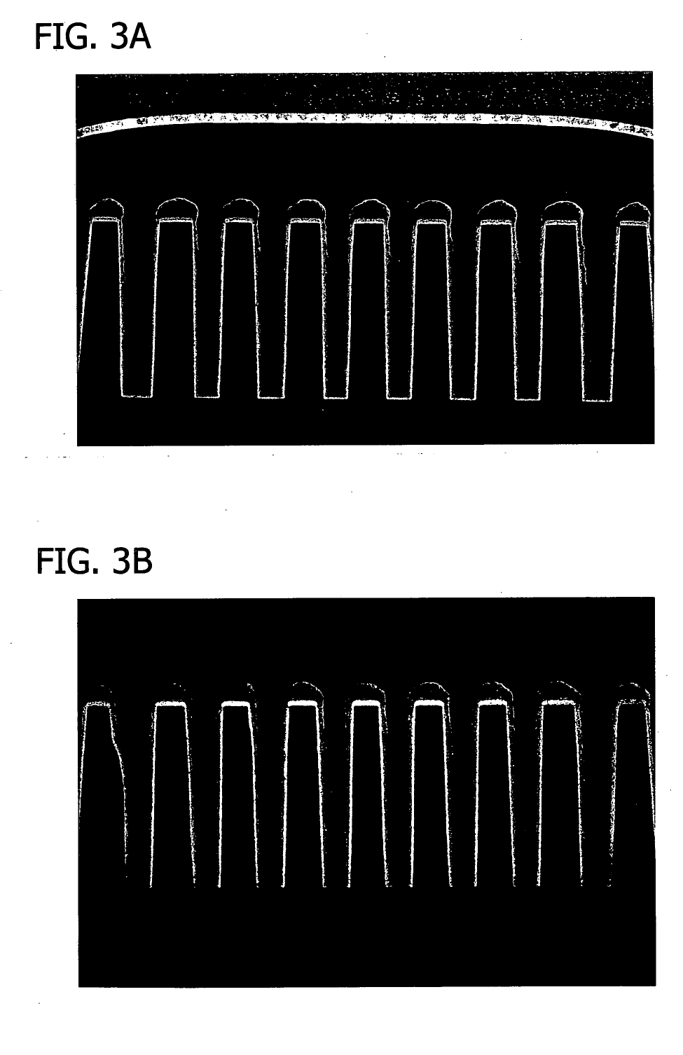

SEM images of the electrolytically plated Cu deposit in the test trenches are shown in FIGS. 3A and 3B. FIG. 3A is an SEM image of the test trenches electrolytically plated with the bath of Example 4. FIG. 3B is an SEM image of the test trenches electrolytically plated with the bath of Comparative Example 4. Both deposits were plated at a current density of 7 mA/cm² for 5.5 seconds to reveal the progression of bottom-up growth. It can be seen from the SEM images that superfilling using the bath of Example 4 achieved more complete via filling than electrolytically superfilling using the bath of Comparative Example 4, thus demonstrating substantially faster fill speed.

### Example 9

Superfilling Test Trenches with Low Acid/High Cu Superfill Electrolytic Plating Bath

Test trenches (140 nm; aspect ratio between 3:1 and 4:1)) were superfilled with Cu using the low acid/high Cu electrolytic plating bath of Example 5 comprising a suppressor of the invention and compared to test trenches superfilled with Cu using the low acid/high Cu electrolytic plating bath of Comparative Example 5 comprising a commercially available suppressor.

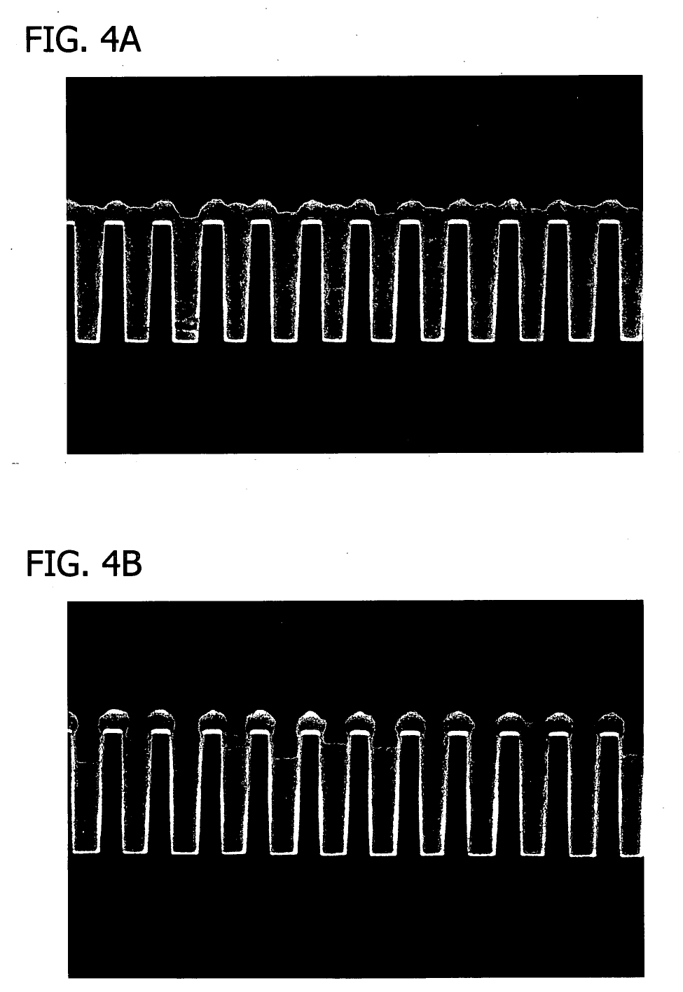

SEM images of the electrolytically plated Cu deposit in the test trenches are shown in FIGS. 4A and 4B. FIG. 4A is an SEM image of the test trenches electrolytically plated with the bath of Example 5. FIG. 4B is an SEM image of the test trenches electrolytically plated with the bath of Comparative Example 5. Both deposits were plated at a current density of 3.5 mA/cm² for 20 seconds to reveal the progression of bottom-up growth. It can be seen from the SEM images that superfilling using the bath of Example 5 achieved more complete via filling than electrolytically superfilling using the bath of Comparative Example 5, thus demonstrating substantially faster fill speed.

When introducing elements of the present invention or the preferred embodiment(s) thereof, the articles “a”, “an”, “the” and “said” are intended to mean that there are one or more of the elements. For example, that the foregoing description and following claims refer to “an” interconnect means that there are one or more such interconnects. The terms “comprising”, “including” and “having” are intended to be inclusive and mean that there may be additional elements other than the listed elements.

As various changes could be made in the above without departing from the scope of the invention, it is intended that all matter contained in the above description and shown in the accompanying drawings shall be interpreted as illustrative and not in a limiting sense. The scope of invention is defined by the appended claims and modifications to the embodiments above may be made that do not depart from the scope of the invention.

What is claimed is:

1. A method for electroplating a copper deposit onto a semiconductor integrated circuit device substrate with electrical interconnect features including submicron-sized features having bottoms, sidewalls, and top openings, the method comprising:
immersing the semiconductor integrated circuit device substrate into the electrolytic plating composition comprising an acid, a source of Cu ions in an amount sufficient to electrolytically deposit Cu onto the substrate and into the electrical interconnect features, and a suppressor compound which is a polyether chain covalently bonded to an initiating moiety comprising an ether group derived from an alcohol, the suppressor compound being bath soluble and bath compatible and having the following structure: 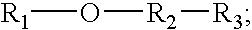
wherein
R₁ is an initiating moiety derived from a substituted or unsubstituted acyclic alcohol having between 1 and about 12 carbons, a substituted or unsubstituted cyclic alcohol preferably having 5 to 7 carbons, or a polyol comprising a hydroxyl group;
R₂ is a random polyether chain comprising EO units and PO units; and
R₃ is selected from the group consisting of hydrogen, substituted or unsubstituted alkyl group, aryl group, aralkyl, or heteroaryl group; and
supplying electrical current to the electrolytic composition to deposit Cu onto the substrate and superfill the submicron-sized features by rapid bottom-up deposition.

2. The method of claim 1 wherein the initiating moiety is derived from n-butanol and the suppressor compound has the following structure: 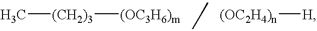
wherein n is between 1 and about 200 and m is between 1 and about 200.

3. The method of claim 2 wherein n is at least about 29 and m is at least about 22.

4. The method of claim 1 wherein the suppressor compound has a molecular weight between about 3000 g/mole and about 4000 g/mole.

5. The method of claim 1 wherein the suppressor compound has an EO:PO weight ratio between about 45:55 and about 55:45.

6. The method of claim 1 wherein the suppressor compound has a molecular weight between about 3000 g/mole and about 4000 g/mole and has an EO:PO weight ratio between about 45:55 and about 55:45.

7. The method of claim 1 wherein the Cu ions are present in an initial concentration between about 35 and about 60 g/L and the acid is present in an initial concentration between about 5 and about 30 g/L.

8. The method of claim 1 wherein the Cu ions are present in an initial concentration between about 35 and about 60 g/L and the acid is present in an initial concentration between about 10 and about 15 g/L.

9. The method of claim 1 wherein the Cu ions are present in an initial concentration between about 46 and about 60 g/L and the acid is present in an initial concentration between about 5 and about 30 g/L.

10. The method of claim 1 wherein the Cu ions are present in an initial concentration between about 48 and about 52 g/L and the acid is present in an initial concentration between about 5 and about 30 g/L.

11. The method of claim 1 wherein the Cu ions are present in an initial concentration between about 38 and about 42 g/L and the acid is present in an initial concentration between about 10 and about 15 g/L.

12. The method of claim 1 wherein said initiating moiety is an alcohol comprising a short chain hydrocarbon having between about four and about ten carbons.

13. The method of claim 1 wherein said initiating moiety is an alcohol selected from the group consisting of n-butanol, iso-butanol, tert-butanol, 1,2-butanediol, 1,3-butanediol, and 1,4-butanediol.

14. The method of claim 1 wherein the suppressor compound is present in an initial concentration between about 100 mg/L and about 300 mg/L.

15. The method of claim 1 wherein the polyether suppressor comprises the structure: 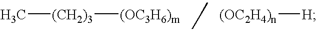
wherein n can be between 1 and about 120 and m can be between 1 and about 120 and the number ratio of n:m is such that the suppressor compound comprises about 50% by weight EO units and about 50% by weight PO units.

16. A method for electroplating a copper deposit onto a semiconductor integrated circuit device substrate with electrical interconnect features including submicron-sized features having bottoms, sidewalls, and top openings, the method comprising:
immersing the semiconductor integrated circuit device substrate into the electrolytic plating composition comprising an acid, a source of Cu ions in an amount sufficient to electrolytically deposit Cu onto the substrate and into the electrical interconnect features, and a suppressor compound which is a PO/EO random copolymer being bath soluble and bath compatible and having the structure: 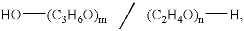
wherein n is between 1 and about 550, m is between 1 and about 125, and the suppressor compound has a molecular weight of at least about 2800 g/mole; and
supplying electrical current to the electrolytic composition to deposit Cu onto the substrate and superfill the submicron-sized features by rapid bottom-up deposition.

17. The method of claim 16 wherein the suppressor compound has a molecular weight between about 10,000 and about 12,000 g/mole.

18. The method of claim 16 wherein the suppressor compound has an EO:PO weight ratio between about 65:35 and about 75:25.

19. The method of claim 16 wherein the suppressor compound has a molecular weight between about 10,000 and about 12,000 g/mole, and an EO:PO weight ratio between about 65:35 and about 75:25.

20. The method of claim 16 wherein the suppressor compound has a molecular weight of about 12,000 g/mole and an EO:PO weight ratio of about 75:25.

21. An electrolytic plating composition for electrolytically plating a copper deposit onto a semiconductor integrated circuit device substrate with electrical interconnect features including submicron-sized features having bottoms, sidewalls, and top openings, the composition comprising:
an acid;
a source of Cu ions in an amount sufficient to electrolytically deposit Cu onto the substrate and into the electrical interconnect features; and
a suppressor compound which is a PO/EO random copolymer being bath soluble and bath compatible, the suppressor compound having a structure selected from between (a) and (b): 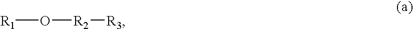
wherein
R₁ is an initiating moiety derived from a substituted or unsubstituted acyclic alcohol having between 1 and about 12 carbons, a substituted or unsubstituted cyclic alcohol preferably having 5 to 7 carbons, or a polyol comprising a hydroxyl group;
R₂ is a random polyether chain comprising EO units and PO units; and
R₃ is selected from the group consisting of hydrogen, substituted or unsubstituted alkyl group, aryl group, aralkyl, or heteroaryl group; and 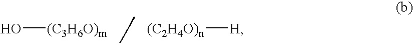
wherein
n is between 1 and about 550;
m is between 1 and about 125; and
the suppressor compound has a molecular weight of at least about 2800 g/mole.

22. The electrolytic plating composition of claim 21 wherein the Cu ions are present in an initial concentration between about 35 and about 60 g/L and the acid is present in an initial concentration between about 5 and about 30 g/L.

23. The electrolytic plating composition of claim 21 wherein the suppressor compound has structure (a) and said initiating moiety is an alcohol selected from the group consisting of n-butanol, iso-butanol, tert-butanol, 1,2-butanediol, 1,3-butanediol, and 1,4-butanediol.

24. The electrolytic plating composition of claim 21 wherein the suppressor compound has structure (a), the initiating moiety is derived from n-butanol, and the suppressor compound has the following structure: 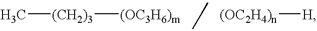
wherein n is between 1 and about 200 and m is between 1 and about 200.

25. The electrolytic plating composition of claim 24 wherein the number ratio of n:m is such that the suppressor compound comprises about 50% by weight EO units and about 50% by weight PO units.

26. The electrolytic plating composition of claim 24 wherein the suppressor compound has a molecular weight between about 3000 g/mole and about 4000 g/mole.

27. The electrolytic plating composition of claim 21 wherein the suppressor compound has structure (b) and has a molecular weight between about 10,000 and about 12,000 g/mole.

28. The electrolytic plating composition of claim 21 wherein the suppressor compound has structure (b) and has an EO:PO weight ratio between about 65:35 and about 75:25.
